(19) United States
(12) Patent Application Publication
(10) Pub. No.: US 2009/0186581 A1
(43) Pub. Date: Jul. 23, 2009

(54) WIRELESS ACCESSORY FOR ELECTRONIC DEVICE

(76) Inventors: Paul P. Griffin, JR., Nashville, TN (US); Robert St. Clair Donovan, Auburn, AL (US)

Correspondence Address: HORNKOHL INTELLECTUAL PROPERTY LAW, P.L.L.C, P.O. BOX 210584, NASHVILLE, TN, 37221, US

(21) Appl. No.: 12/354,670

(22) Filed: Jan. 15, 2009

Related U.S. Application Data
(63) Continuation-in-part of application No. 11/779,862, filed on Jul. 18, 2007.

(51) Int. Cl. H04B 7/00; H03D 7/16; H04M 1/00

(52) U.S. Cl. 455/41.3; 455/131; 455/575.1

(57) ABSTRACT

An improved accessory for an electronic device that allows the device to interface with a standard radio receiver or another electronic device using an incompatible digital transmission format. The accessory includes a digital transceiver for establishing digital communications with a first remote device having a digital transceiver. The accessory receives audio data from the device over the digital wireless channel and produces an FM broadcast output signal based upon the received digital audio data. Thus, music from a personal computer or digital music player can be listened to over a standard radio receiver. The accessory can also be configured to produce a Wi-Fi or Bluetooth formatted output such that the audio data can be transmitted to a previously incompatible radio or headphone receiver. The user inputs of the portable electronic device can preferably be used to control functions of the accessory and the device's display to display the selected transmission frequency or channel of the accessory.

### CROSS-REFERENCES TO RELATED APPLICATIONS

This application is continuation-in-part of pending U.S. patent application Ser. No. 11/779,862, filed Jul. 18, 2007 which is hereby incorporated by reference, for a Digital Controller and Transmitter for Portable Electronic Device for the invention by Paul P. Griffin, Jr. et al. and Provisional Patent Application Ser. No. 61/012,110 filed Jan. 15, 2008.

### STATEMENT REGARDING FEDERALLY SPONSORED RESEARCH OR DEVELOPMENT

Not Applicable.

### REFERENCE TO SEQUENCE LISTING OR COMPUTER PROGRAM LISTING APPENDIX

Not Applicable.

### BACKGROUND OF THE INVENTION

Transmitters for portable electronic devices that allow an analog audio signal to be transmitted from the device to an FM radio are known in the prior art. These devices receive the analog audio output from the portable electronic device and convert the output into a frequency or amplitude modulated signal that is transmitted to a standard radio receiver. Unfortunately, the analog output signal may be distorted by the modulation and transmission process such that the audio is slightly degraded. Therefore, what is needed is an improved device for transmitting audio to an FM radio.

Wi-Fi, also unofficially known as Wireless Fidelity, is a wireless technology based on IEEE 802.11 standards. Common applications for Wi-Fi include Internet and VoIP phone access, gaming, and network connectivity for consumer electronics such as televisions, DVD players, and digital cameras. Digital transmitters, such as Wi-Fi transceivers, allow a user to wirelessly and digitally connect the device to a remote device. Unfortunately, these Wi-Fi transmitters will not work with standard FM radios or Bluetooth equipped headphones. Bluetooth is an industrial specification for wireless personal area networks. Bluetooth provides a way to connect and exchange information between devices such as mobile phones, laptops, PCs, printers, digital cameras, and video game consoles over a secure, globally unlicensed short-range radio frequency. Bluetooth is acceptable for situations when two or more devices are in close proximity to each other and a large bandwidth is not required. Bluetooth is popular because it simplifies the discovery and setup of services by eliminating network addresses, permissions and other requirements of Wi-Fi networks. Conversely, Wi-Fi requires more setup, but is better suited for operating full-scale networks because it enables a faster connection, better range from the base station, and better security than Bluetooth. Thus, digital transmitters are configured to work with a particular type of electronic device using a particular digital transmission format. Therefore, what is needed is an inexpensive device for interfacing different digital formats.

Accessories for electronic devices provide the devices with additional functionality. These accessories are typically only compatible with one type of electronic device. Unfortunately, due to the large number of different types of electronic devices, large numbers of different accessories must be designed and stocked to accommodate all of the available devices. Therefore, what is needed is an accessory that is compatible with a large number of different devices.

### BRIEF SUMMARY OF THE INVENTION

An embodiment of the present invention is directed toward an accessory for coupling with an electronic device. The accessory is adapted to be mounted in a 12-volt car outlet. The accessory includes a Wi-Fi and Bluetooth digital receiver for wirelessly receiving digital data from the electronic device. A signal generator and modulator produce an analog FM frequency modulated signal based upon digital data received from the electronic device. A transmitter transmits the analog frequency modulated signal to a remote radio receiver. The accessory automatically identifies an open frequency for transmitting the analog frequency modulated signal to the remote radio receiver. The accessory instructs the electronic device to display a transmission frequency of the accessory on a display of the electronic device. A set of user inputs on the accessory can be used to control selected functions of the electronic device. The accessory can also detect manipulation of a user input of the electronic device and alter a function of the accessory based upon the detected manipulation. Software residing on the electronic device allows a user to configure the accessory to perform the desired functions. The accessory can function as a parasitic device that obtains power from the electronic device when the accessory is electrically coupled to the electronic device. The accessory also includes a digital encoder for converting the digital data to formatted digital data and a digital transmitter for transmitting the formatted digital data to a remote digital receiver in a second electronic device.

Another embodiment of the present invention is directed toward an accessory for use with an electronic device. The accessory includes a digital wireless transceiver for exchanging digital audio data with the electronic device. A wireless transmitter in the accessory transmits an output signal based upon the digital audio data to a remote radio receiver in a Wi-Fi or Bluetooth format.

Yet another embodiment of the present invention is directed toward a method of transmitting audio data between a first and second electronic device with an accessory adapted to be mounted in a 12-volt car outlet. In accordance with the method, digital audio data is received from the first electronic device with the accessory. An analog output audio signal is produced by the accessory based upon the digital audio data. The analog output audio signal is then transmitted to a remote radio receiver. The analog output audio signal preferably is an FM broadcast frequency modulated signal. The digital audio data may also be reformatted into a Bluetooth or Wi-Fi transmission format and transmitted by the accessory to a second electronic device in accordance with the method.

### BRIEF DESCRIPTION OF THE SEVERAL VIEWS OF THE DRAWINGS

FIG. 1 is an illustration of an accessory constructed in accordance with an embodiment of the present invention adapted to be mounted in a 12-volt outlet;

FIG. 2 is an illustration of an accessory constructed in accordance with an embodiment of the present invention adapted to be coupled directly to a portable electronic device;

FIG. 3 is a functional block diagram of an accessory constructed in accordance with an embodiment of the present invention; and

FIG. 4 is a flow chart of a method of configuring an accessory constructed in accordance with an embodiment of the present invention to work with a selected device and receiver.

### DETAILED DESCRIPTION OF THE INVENTION

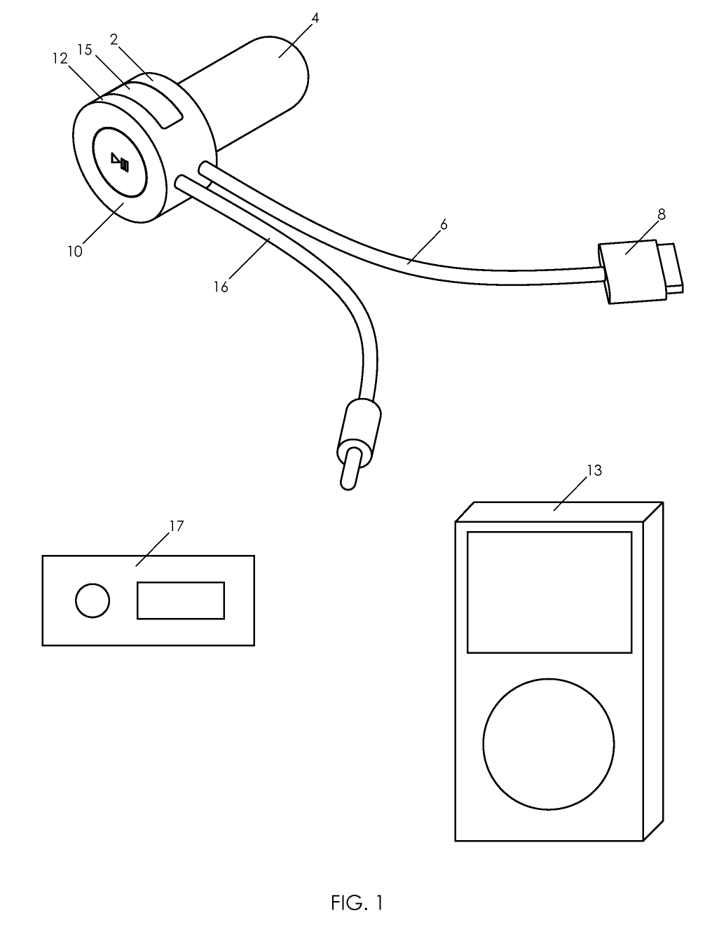

The present invention is directed toward an accessory for an electronic device that transmits information between the electronic device and a remote receiver. Referring now to FIG. 1, an illustration of an accessory 2 for a portable electronic device 13 constructed in accordance with an embodiment of the present invention is shown. The accessory 2 has a lower body portion 4 that is adapted to be inserted into a 12-volt auxiliary power output, i.e., cigarette lighter, of an automobile. In a preferred embodiment of the present invention, the accessory 2 communicates with the electronic device 13 through the use of a Wi-Fi wireless data link. A Wi-Fi transceiver positioned in the accessory 2 body permits the accessory 2 to establish wireless communications with a remote electronic device 13 such as a personal computer or digital music player. Digital music files can then be downloaded from the Wi-Fi equipped electronic device 13 to the accessory 2. The accessory 2 then produces a modulated output that is broadcast to an FM radio receiver 17 on a selected frequency. The frequency is selected by a user interacting with the accessory controls 10 and display 15. The broadcast signal is received by a radio receiver 17, such as a car radio, and broadcast over the radio's speakers. Thus, the accessory 2 allows a user to play digital music from a wireless equipped device 13 over a standard car stereo 17.

The user controls 10, preferably buttons, are positioned on an upper portion 12 of the accessory 2. The user inputs 10 are preferably soft controls that can be repurposed to perform different functions. These inputs 10 are used to control functions, such as play, pause, volume, etc. for the music being received from the device 13 with the accessory 2 and transmitted to the receiver 17. This can be accomplished through the use of internal circuitry and software in the accessory 2. A microprocessor in the accessory 2 is able to communicate with the electronic device 13 through the wireless communication link such that the device's functions can be controlled by the accessory 2. The accessory controls 10 can be used to control functions of the electronic device 13 by retrieving a code associated with the selected function from a memory in the accessory and sending the code to the electronic device 13 through the digital wireless communication link. The device 13 then performs the requested function. A most preferred set of controls 10 is a play, pause, rewind, skip and stop and a volume up/down for a digital music player which is equipped with a Wi-Fi output. However, the controls 10 can be repurposed to control any desired function of the device 13 with which the accessory 2 is designed to work with. A display 15 is included on the upper accessory body 12 to display status information, transmission frequencies or channels, menus and instructions to the user. The display 15 is preferably an organic light emitting device display (OLED).

While the accessory is preferably coupled to the electronic device 13 through a digital wireless connection in a format such as Wi-Fi or Bluetooth, a cable 6 and connector 8 is preferably provided such that the accessory 2 can be directly, electrically coupled to compatible devices 13 if desired. The electrical coupling of the accessory 2 to the device 13 allows the accessory 2 to charge the device 13. Also, while the accessory's output is preferably a frequency modulated broadcast, it can also be a modulated output transmitted over an audio out cable 16. In addition, the digital transceiver used to establish wireless contact with the electronic device 13 can also be used to transfer reformatted digital data to a second computer having a digital transceiver. By equipping the accessory 2 to deal with multiple digital transmission protocols or formats such as both Bluetooth and Wi-Fi, the accessory 2 can be used to transfer data between a first device having a Bluetooth communication link and a second device having a Wi-Fi communication link.

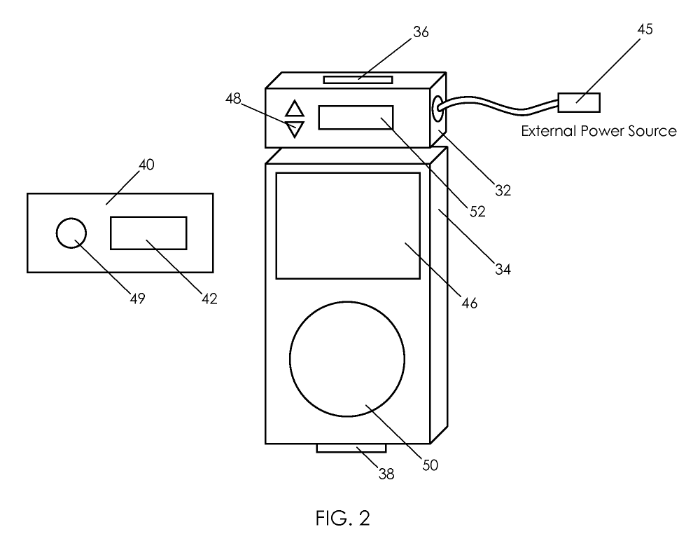

Referring now to FIG. 2, an illustration of an accessory 32 constructed in accordance with a second embodiment of the present invention is shown. The accessory 32 is small portable device with a wireless transceiver. The accessory 32 can communicate with an electronic device 34 through the wireless transceiver and produce an output that is adapted to be received by a remote receiver 40 that is incompatible with the device 34. Most preferably, the accessory 32 receives a digital wireless output from the device 34 and produces a frequency modulated broadcast signal based upon the received input for reception by the remote FM receiver 40. By providing the accessory 32 with wireless analog and digital transceivers and audio out capabilities, the accessory 32 can be designed to work with a much larger number of different types of devices.

The accessory can also be electrically coupled to the device 34 through a coupling connector 36 on the accessory 32 that mates with a corresponding connector 38 on the device 34. This allows the accessory 32 and device 34 to function and be carried as a single unit. Audio data can then be transferred directly from the device 34 to the accessory 32. The accessory 32 can also receive power from the device 34 in a parasitic manner when they are coupled together. Alternatively, an external power source 45 can be coupled to the accessory 32 such that the accessory 32 can charge the device 34 when it is coupled to the accessory 32. The particular type of connector, USB, 30 pin, barrel, etc., that is used to electrically and physically couple the accessory 32 to the device 34 depends upon the type of input/output connector 38 on the device 34 for which the accessory 32 is designed.

In the embodiment of FIG. 2, the accessory 32 contains a digital transmitter that allows data and signals received from the device to be transmitted to the remote receiver 40. An unused channel or frequency is preferably selected by the user for transmission of the audio signal from the accessory 32 to the remote receiver 40 to using the user inputs 48 of the accessory 32. The user inputs 48 of the accessory 32 are preferably a small number of soft buttons that can be reconfigured to control the various functions of the accessory 32 such that the number of user inputs required by the accessory, and their associated costs, are minimized. The accessory 32 can also be configured to automatically search for a clear channel for the transmission.

The accessory 32 can write text to the electronic device's display 46 and the remote receiver's display 42 and repurpose the controls 50 of the electronic device 34 to control functions of the accessory 32, device 34 and receiver 40 as discussed in more detail below. In such an embodiment, the accessory 32 can digitally instruct the receiver 40 to tune to the frequency or channel selected with the controls 50 of the device 34. The accessory controls 48 or device controls 50 can also be used to manipulate accessory 32 generated menus displayed on a display screen 42, 46 or 52 of the accessory 32, portable device 34 or receiver 40. By selecting the proper menus and selections, accessory, device and receiver functions, such as the volume, operating mode, display, etc., can be controlled by a user through manipulation of the controls of the accessory, device or receiver. Which particular controls to use to control which particular functions will be determined based upon the particular type of electronic device 34 and remote receiver 40 for which the accessory 32 is designed or configured.

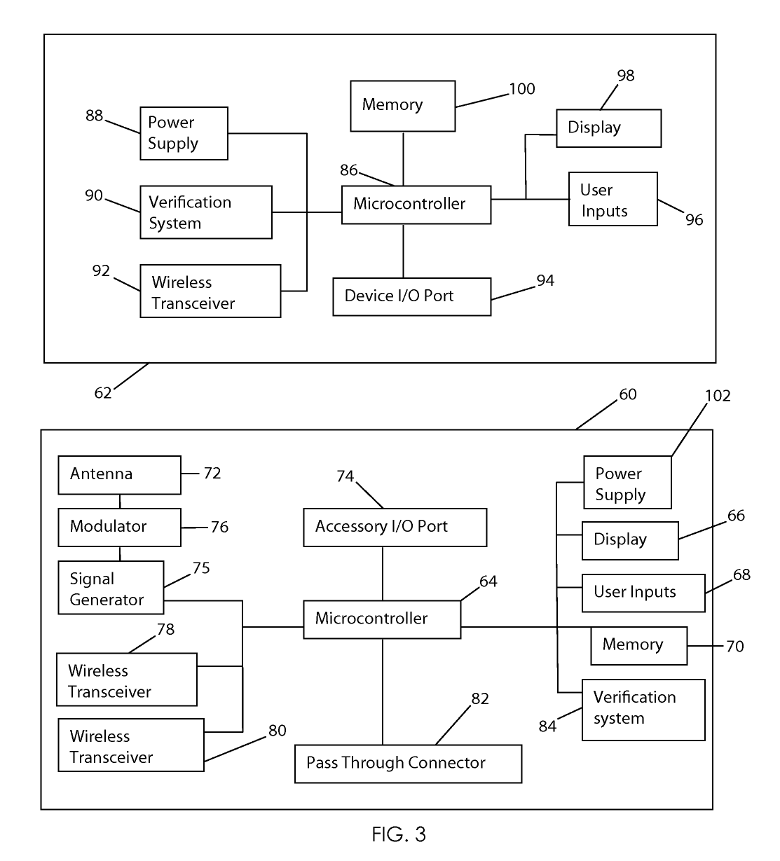

Referring now to FIG. 3, a functional block diagram of an accessory 60 constructed in accordance with an embodiment of the present invention coupled to a an electronic device 62 through a wireless transceiver 78 is shown. A wireless transceiver 92 in the device 62, preferably operating under a Wi-Fi or Bluetooth transmission format, sends digital data and audio files from the device 62 to the digital wireless transceiver 78 of the accessory 60. The accessory 60 has a microcontroller 64 that receives the digital data from the wireless transceiver 78 and instructs a signal generator 75 to produce an analog audio output. The analog audio output is then sent to a modulator 76 that produces a frequency modulated output at a FM broadcast frequency that is applied to an antenna 72 for transmission to a standard FM radio receiver. Since the digital data should be received from the device 62 with no or minimal errors, minimal interference is introduced by the transmission process from the device 62 to a remote FM receiver through the accessory 60. Any alteration in the original signal will be a result of the signal generation and modulation functions of the accessory 60 which can be managed to limit the amount of allowable distortion of the original signal.

The various functions of the accessory 60 are controlled by the microcontroller 64. The microcontroller 64 can be used to alter the transmit frequency of the modulator 76 or the channels or format of the digital wireless transceivers 78 and 80 in response to a user manipulating a user input 68. Alternatively, the accessory 60 can be configured to automatically determine an appropriate transmission frequency. In such an embodiment, the accessory 60 scans the available stations or channels for an open frequency. The accessory 60 then displays at least one available frequency on the display 66 such that a user can select a desired open frequency for the transmission. These selected frequencies can be stored in presets for later reference and selection through the user inputs 68. The selected transmission frequency or channel for the accessory 60 is displayed on the display 66 of the accessory.

The accessory microcontroller 64 communicates with the microcontroller 86 of the device 62 through the wireless transceivers 78 and 92. By establishing digital communications between the controllers 64 and 86, the accessory 60 can exchange digital control information with the device 62. The accessory 60 can also read data from and write data to the memory 100 of the device 62. Thus, the accessory 62 can respond to manipulation of the user inputs 96 of the device 62 and display information on the display 98 of the device 62. A preferred embodiment of the present invention instructs the device 62 to display the currently selected transmitter frequency or channel of the accessory 60 on the display screen 98 of the device 62. By utilizing the display 98 of the device 62, the cost of the components required to implement the accessory 60 is minimized. In addition, the accessory 60 can display menus on the display screen 98 on the device 62 and allow a user to manipulate the menus through the use of the controls 96 of the device 62 to control the functions of the accessory 60.

A second wireless transceiver 80 in the accessory 60 allows the accessory to convert digital transmissions received from the device 62 in a first format, such as Wi-Fi, and output a digital data file in a second format, such as HD radio or Bluetooth, for reception by a remote digital receiver. Thus, audio files from a personal computer can be converted into Bluetooth signals for reception by a cellular telephone headset by an accessory 60 constructed in accordance with an embodiment of the present invention.

The accessory 60 may also be coupled to the device 62 through a wired input/output port 74 that is electrically connected to a corresponding input/output port 94 on device 62. A series of connection lines provide electrical connections between selected pins of the device input/out port 94 and the accessory input/output port 74. The ports can be used to supply power from a power supply 88 of the device 62 to the accessory 60. In the embodiment shown, the possible electrical connections between the device 62 and accessory 60 include a digital data channel, an analog audio signal line and a power connection.

The accessory user inputs 68 are preferably soft controls that can be reconfigured to perform any desired functions. Conversion codes and routines for converting device inputs 96 and accessory inputs 68 into desired functions can be stored in an accessory memory 70 or device memory 100. For example, the tuning controls of the device 62 can be repurposed to control the tuning band/range of the accessory's modulator 76 to enable geographic localization of the modulator's band/range or pre-emphasis settings for different geographic areas such as Japan, the European Union and the United States. The device's volume control can be also used to control the output volume level of the accessory's transmitter. When the volume output is adjusted through the device's user inputs 96, the accessory attenuates its output so that the volume level of the accessory 60 moves up or down at the same rate as the device 62. As yet another example, seek up and seek down device controls can be repurposed to control a seek up and seek down function for the accessory. Similarly, the mono/stereo reception control of the device can control the mono/stereo transmitter transmission modes. As yet further examples, the presets on the device can function as presets for the accessory transmitter and the device's On/Sleep/Off commands can place the accessory into corresponding modes. By configuring the accessory 60 and repurposing the controls of the accessory with software, which can reside in the device 62, the accessory 60 can be constructed from fewer components. This results in accessory that is less bulky and expensive and more reliable.

The digital audio file received from the device 62 can also be encoded as a digital radio signal in a format such as HD radio by the accessory 60 such that the output of the digital wireless transceiver 80 can be received by a digital radio receiver. HD digital radio simultaneously transmits a digital version of the analog broadcast and a second digital channel which can be used for alternate radio programming or data services such as song information, weather reports and car navigation updates. HD digital radio transmits the digital channels in unused portions of the same AM and FM channels used for the old analog stations. The digital radio receiver can receive control data in data fields which can be used to control functions of the digital receiver and display messages from the digital broadcaster. Most often, these data fields are used to display program service data that consists of a number of different fields which are displayed on HD radio receivers, including: song title, program title, artist name, album name, and music genre. The accessory 60 can repurpose these fields such that new information such as text messages, advertisements, logos, song lyrics, etc. from the device 62 or accessory 60 can be transmitted to the remote digital radio receiver and displayed on a display screen of the receiver. Custom messages can also be entered on the device 62 by the user and transmitted to the remote receiver for display or audio reproduction if desired. Longer messages can be scrolled across the display of the HD receiver. An embodiment of the present invention can also be configured such that a user can receive messages with their mobile phone and transmit the messages to their car stereo through the accessory.

The audio file from the device 62 can also be encoded as a satellite radio signal by the accessory 60 such that the output of the digital transceiver can be received by a satellite radio equipped receiver. A satellite radio transmitter typically operates in the “S” band (2.3 GHz) and provides Digital Audio Radio Service (DARS). In one embodiment, the accessory includes logic and circuitry for analog, satellite and HD radio capabilities such that a user can select between the transmission formats using the user inputs and of the device or accessory.

An accessory 60 constructed in accordance with an embodiment of the present invention may also include a verification system 84 that cooperates with a verification system 90 in the device 62 to verify that the accessory is being used by an approved electronic device or that the accessory is an approved accessory for the device. The verification system 84 and 90 can use an identification resistor, a digital certificate, validation code or any other type of identification system or circuitry to verify that the device and accessory are produced by approved entities. Digital rights management software may also be included in the accessory to verify the authenticity of any copyrighted material being transmitted from the device to the remote receiver by the accessory.

An accessory 60 constructed in accordance with an embodiment of the present invention also preferably includes a pass through connector 82 that allows a second accessory to couple to an output or input port of the electronic device 62 through the accessory 60. For example, the accessory may have a USB port that allows an external device to be coupled through the accessory to the USB port of a digital music player if the accessory covers the USB port of the device when it is coupled to the device. Alternatively, the pass through connector 82 can be used to supply power to the device through the accessory 60 or couple an accessory having a different type of I/O port than the device I/O port 94.

The accessory 60 and device 62 can be powered in a number of different manners depending upon the configuration of the device 62 with which the accessory 60 is constructed to work. The accessory 60 may be a parasitic device that takes its power from the power supply 88 of the electronic device 62 if the device power supply 88 is capable of supplying the power required by the digital circuitry of the accessory 60. However, the accessory may also contain an internal power source 102 for powering the accessory 60 and charging the portable electronic device 62. The internal power supply 102 is a battery or a connection to an external power supply, such as a 12-volt car outlet. Power conversion and conditioning circuitry may be included in the power supply 102 if necessary to provide appropriately conditioned power to the device 62 and accessory 60.

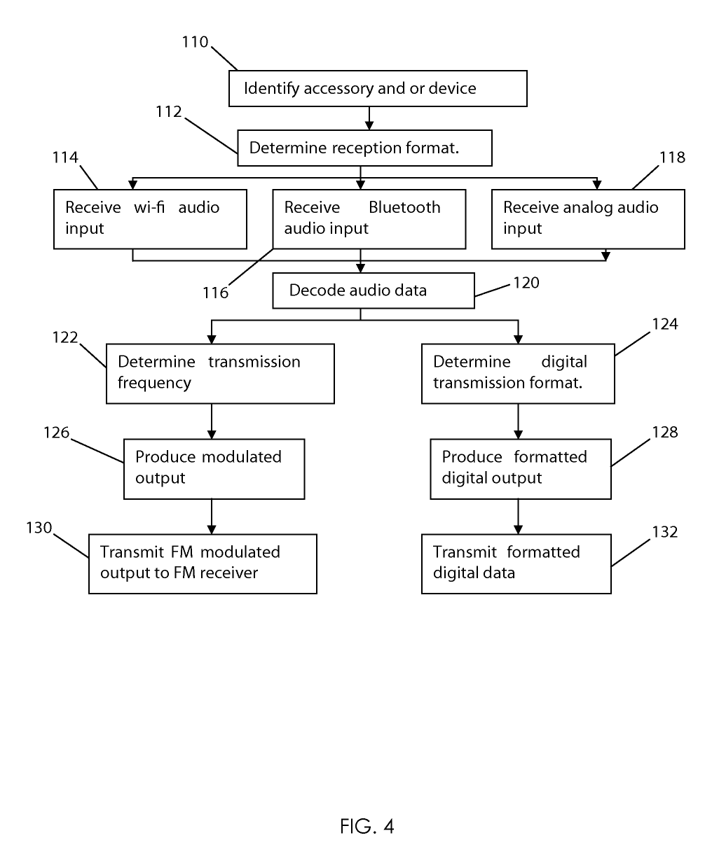

Referring now to FIG. 4, a flow chart of a method of configuring an accessory constructed in accordance with an embodiment of the present invention to work with a selected device and remote receiver is shown. The method commences in step 110 with the identifying of the accessory and/or device. Once the device is identified, the accessory identifies the reception format for receiving data from the device in step 112. In steps, 114, 116 and 118, the accessory is configured to receive the appropriate, Wi-Fi, Bluetooth or analog audio input. The method then proceeds to step 120 wherein the audio data is decoded. The method of decoding depends upon the format of the received audio data.

If the accessory is configured to produce a frequency modulated output, the method proceeds to step 122 wherein a transmission frequency for the accessory is determined. An FM modulated output is produced in step 126 and the modulated output transmitted to a remote FM receiver in step 130. If the accessory is configured to produce a formatted digital output, the method proceeds to step 124 wherein the particular digital transmission format to use is determined. A formatted digital output is then produced in step 128 and the formatted data transmitted to a remote digital receiver in step 132.

Although there have been described particular embodiments of the present invention of a new and useful WIRELESS ACCESSORY FOR ELECTRONIC DEVICE, it is not intended that such references be construed as limitations upon the scope of this invention except as set forth in the following claims.

What is claimed is:

1. An accessory for coupling with an electronic device, said accessory comprising:
a digital receiver for wirelessly receiving digital data from said electronic device;
a signal generator and modulator for producing an analog frequency modulated signal based upon said digital data received from said electronic device; and
a transmitter for transmitting said analog frequency modulated signal to a remote radio receiver.

2. The accessory of claim 1 wherein said accessory is adapted to be mounted in a 12-volt car outlet.

3. The accessory of claim 1 wherein said accessory automatically identifies an open frequency for transmitting said analog frequency modulated signal to said remote radio receiver.

4. The accessory of claim 1 wherein said digital receiver is a Wi-Fi transceiver.

5. The accessory of claim 1 wherein said digital receiver is a Bluetooth transceiver.

6. The accessory of claim 1 wherein a set of user inputs on said accessory can control a function of said electronic device.

7. The accessory of claim 1 wherein said accessory instructs said electronic device to display a transmission frequency of said accessory on a display of said electronic device.

8. The accessory of claim 1 wherein said accessory detects manipulation of a user input of said electronic device and alters a function of said accessory based upon said detected manipulation.

9. The accessory of claim 1 wherein said accessory is a parasitic device that obtains power from said electronic device when said accessory is electrically coupled to said electronic device.

10. The accessory of claim 1 wherein said analog frequency modulated audio signal is an FM broadcast frequency signal.

11. The accessory of claim 1 further comprising a digital encoder for converting said digital data to reformatted digital data and transmitting said reformatted digital data to a remote digital receiver in a second electronic device.

12. An accessory for use with an electronic device, said accessory comprising:
a digital wireless transceiver for exchanging digital audio data with said electronic device; and
a wireless transmitter for transmitting an output signal based upon said digital audio data to a remote radio receiver.

13. The accessory of claim 12 wherein said accessory is configured to be mounted in a 12-volt car outlet.

14. The accessory of claim 12 wherein said output signal is an FM broadcast signal.

15. The accessory of claim 12 wherein said output signal is in a Wi-Fi or Bluetooth format.

16. A method of transmitting audio data between a first and second electronic device with an accessory adapted to be mounted in a 12-volt car outlet, said method comprising the steps of:
receiving digital audio data from said first electronic device with said accessory;
producing an analog output audio signal based upon said digital audio data with said accessory; and
transmitting said analog output audio signal to a remote radio receiver.

17. The method of claim 16 wherein said analog output audio signal further comprises an FM broadcast signal.

18. The method of claim 16 wherein said accessory is adapted to be mounted in a 12-volt car outlet.

19. The method of claim 16 further comprising the step of reformatting said digital audio data and transmitting said reformatted digital data with said accessory.

20. The method of claim 19 wherein said digital audio data is reformatted into a Bluetooth or Wi-Fi transmission format.
